(19) United States
(12) Patent Application Publication
(10) Pub. No.: US 2025/0151263 A1
(43) Pub. Date: May 8, 2025

(54) MEMORY DEVICE AND MANUFACTURING METHOD THEREOF

(71) Applicant: NANYA TECHNOLOGY CORPORATION, New Taipei city (TW)

(72) Inventor: Chung-Lin HUANG, Taoyuan City (TW)

(21) Appl. No.: 18/500,605

(22) Filed: Nov. 2, 2023

(51) Int. Cl. H10B 12/00

(52) U.S. Cl. CPC H10B 12/488; H10B 12/02; H10B 12/482; H10B 12/485

(57) ABSTRACT

A memory device includes a substrate, a word line buried in the substrate and extending in a first direction, a word line cap layer over the word line, a landing pad over and in contact with the substrate and the word line cap layer, a cell contact over and in contact with the landing pad, and a bit line over the word line and extending in a second direction perpendicular to the first direction.

### BACKGROUND

### Field of Disclosure

The present disclosure relates to a memory device and a manufacturing method thereof.

### Description of Related Art

Memory cells in the dynamic random access memory (DRAM) have been scaled down continuously to achieve a larger number of the memory cells in a unit area. However, some issues of manufacturing the memory cells may arise from the scaling down process of DRAM. For example, the overlay between two different components may become difficult.

### SUMMARY

Some embodiments of the present disclosure provide a memory device, including a substrate, a word line buried in the substrate and extending in a first direction, a word line cap layer over the word line, a landing pad over and in contact with the substrate and the word line cap layer, a cell contact over and in contact with the landing pad, and a bit line over the word line and extending in a second direction perpendicular to the first direction.

In some embodiments, the substrate and the landing pad are made of silicon.

In some embodiments, the memory device further includes an isolation structure buried in the substrate and in contact with the landing pad.

In some embodiments, the memory device further includes a dielectric layer covering the landing pad, the word line cap layer and the isolation structure.

In some embodiments, the dielectric layer is in contact with the cell contact and the landing pad.

In some embodiments, a bottom of the landing pad is substantially level with a top surface of the isolation structure.

In some embodiments, the substrate has a portion protruding over a top surface of the isolation structure, and the landing pad is in contact with sidewalls of the portion of the substrate.

In some embodiments, the memory device further includes a bit line contact below the bit line, wherein a bottom of the bit line contact is lower than a bottom of the landing pad.

In some embodiments, a bottom of the landing pad is substantially level with a top surface of the word line cap layer.

In some embodiments, a portion of the landing pad is between the cell contact and the word line cap layer.

Some embodiments of the present disclosure provide a manufacturing method of a memory device including forming a word line and a word line cap layer buried in a substrate, in which the word line extends in a first direction, and the word line cap layer is over the word line, A mask layer is formed over the substrate, in which the mask layer exposes a first portion of the substrate. A selective epitaxial growth process is performed to form a landing pad over the first portion of the substrate. A dielectric layer is formed over the landing pad, the substrate and the word line cap layer. A cell contact is formed penetrating the dielectric layer and in contact with the landing pad.

In some embodiments, during the selective epitaxial growth process, the landing pad extends to a top surface of the word line cap layer.

In some embodiments, the manufacturing method further includes removing the mask layer to exposing a second portion of the substrate after forming the dielectric layer, forming a bit line contact hole in the substrate by using the dielectric layer as mask, and forming a bit line contact in the bit line contact hole.

In some embodiments, the manufacturing method further includes forming a bit line over the bit line contact and the dielectric layer, forming a bit line cap layer over the bit line, and forming a spacer lining sidewalls of the bit line contact, the bit line and the bit line cap layer.

In some embodiments, the spacer and the landing pad are separated by the dielectric layer.

In some embodiments, the bit line and the landing pad are separated by the dielectric layer.

In some embodiments, after forming the cell contact, a portion of the landing pad is between the cell contact and the word line cap layer.

In some embodiments, a bottom of the bit line contact hole is lower than the landing pad.

In some embodiments, the manufacturing method further includes performing a cleaning process prior to the selective epitaxial growth process, such that sidewalls of the first portion of the substrate are exposed after the cleaning process.

In some embodiments, the landing pads are in contact with the sidewalls of the first portion of the substrate.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a circuit diagram of the memory device in some embodiments of the present disclosure.

FIG. 2 illustrates a top view of an intermediate stage of forming a memory device in some embodiments of the present disclosure.

FIGS. 3A and 4A illustrate cross-section views of forming the memory device taken along line X-X′ in FIG. 2.

FIGS. 3B and 4B illustrate cross-section views of forming the memory device taken along line Y-Y′ in FIG. 2.

FIG. 5 illustrates a top view of an intermediate stage of forming the memory device in some embodiments of the present disclosure.

FIGS. 6A, 7A, 8A, 9A and 10A illustrate cross-section view of forming the memory device taken along line X-X′ in FIG. 5.

FIGS. 6B, 7B, 8B, 9B and 10B illustrate cross-section views of forming the memory device taken along line Y-Y′ in FIG. 5.

FIG. 11 illustrates a top view of an intermediate stage of forming the memory device in some embodiments of the present disclosure.

FIG. 12A illustrate a cross-section view of forming the memory device taken along line X-X′ in FIG. 11.

FIG. 12B illustrate a cross-section view of forming the memory device taken along line Y-Y′ in FIG. 11.

FIGS. 13A, 14A and 15A illustrate cross-section views of forming the memory device taken along line X-X′ in FIG. 5 in some other embodiments.

FIGS. 13B, 14B and 15B illustrate cross-section views of forming the memory device taken along line Y-Y′ in FIG. 5 in some other embodiments.

### DETAILED DESCRIPTION

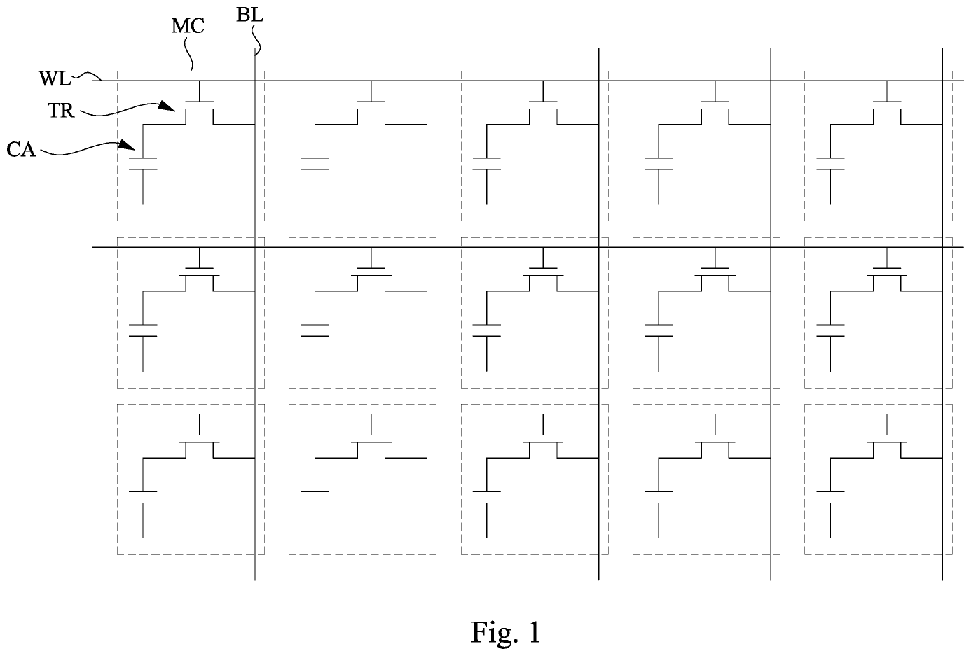

FIG. 1 illustrates a circuit diagram of the memory device in some embodiments of the present disclosure. Referring to FIG. 1, the memory device (e.g., dynamic random access memory, DRAM) may include a plurality of memory cells MC. A typical DRAM memory cell incorporates a capacitor CA and a transistor TR in which the capacitor CA temporarily store data based on the charged state of the capacitor CA. A bit line BL is electrically connected to a source region of the transistor TR, and a word line WL is electrically connected to a gate region of the transistor TR. The capacitor CA is electrically connected to the respective transistor by a cell contact. In the present disclosure, a contact area between the cell contact and the transistor is enlarged, and thus the transistor and the respective capacitor are well connected. Therefore, the cell contact does not have to perfectly overlay the transistor.

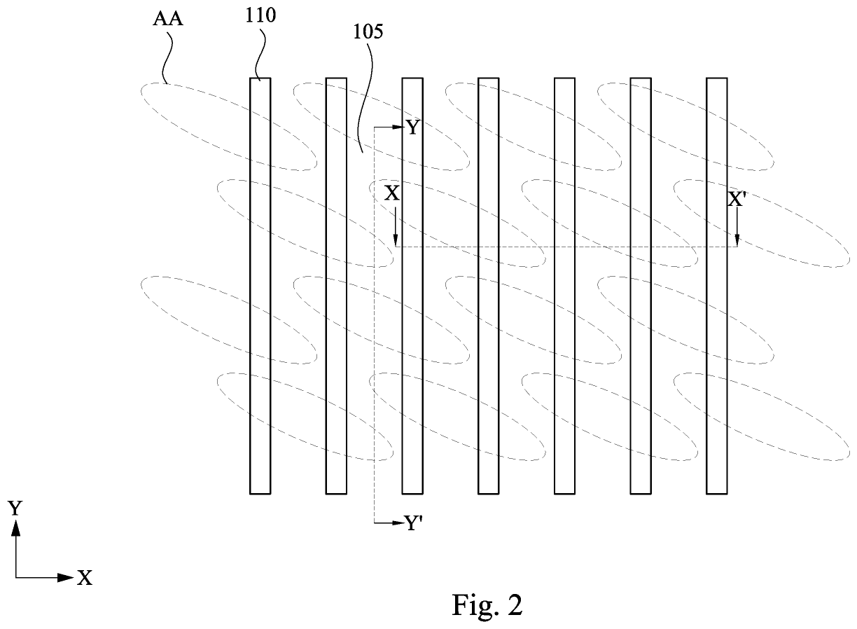

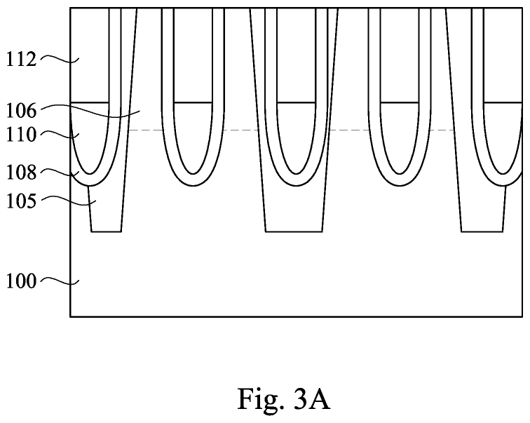

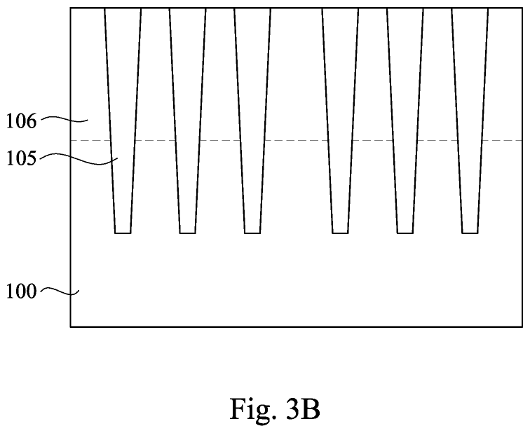

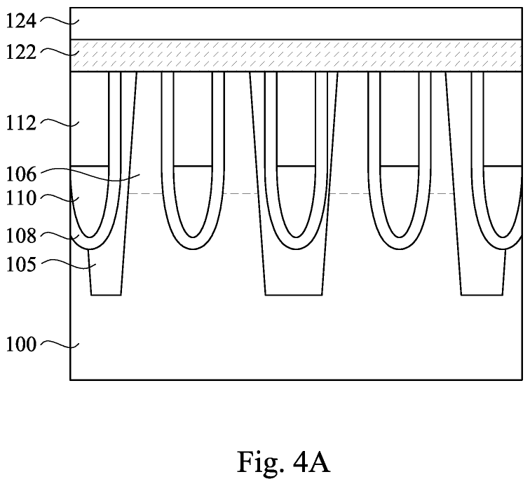

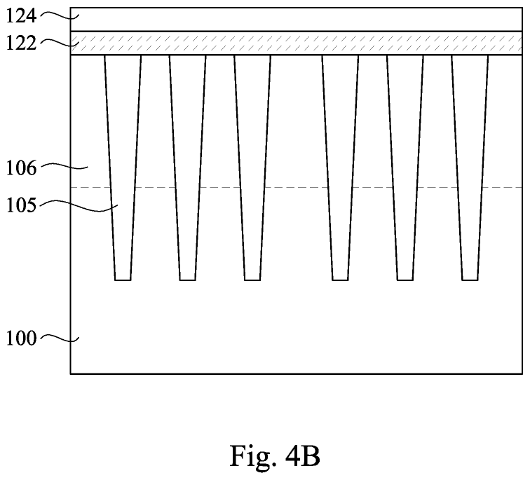

FIG. 2 illustrates a top view of an intermediate stage of forming a memory device in some embodiments of the present disclosure. FIGS. 3A and 4A illustrate cross-section views of forming the memory device taken along line X-X′ in FIG. 2, and FIGS. 3B and 4B illustrate cross-section views of forming the memory device taken along line Y-Y′ in FIG. 2. It is noted that FIG. 2 only illustrates a part of the components, and other components are omitted for simplicity. Referring to FIGS. 2, 3A and 3B, a substrate 100 is provided, and isolation structures 105 are formed in the substrate 100. The region of the substrate 100 that is not covered by the isolation structures 105 may be referred to as active areas AA in FIG. 2, and the active areas AA may be referred as to diffusion regions of transistors. In some embodiments, the substrate 100 may be made of silicon, and the isolation structures 105 are made of dielectric materials, such as silicon oxide. Subsequently, dielectric layers 108, word lines 110 and word line cap layers 112 are formed buried in the substrate 100. The word line cap layers 112 are over the word lines 110, the word line cap layers 112 and the word lines 110 are formed in the dielectric layers 108, and the word line cap layers 112 and the word lines 110 extend along a first direction (such as along Y-direction). The word line cap layers 112 and the word lines 110 cross over the active areas AA and the isolation structures 105 and in contact with the isolation structures 105. The top surface of the word line cap layers 112 is substantially level with a top surface of the substrate 100. In some embodiments, the dielectric layers 108 may be made of oxide, the word lines 110 may be made of conductive material, such as metal (such as tungsten), and the word line cap layers 112 may be made of dielectric material.

The substrate 100 may include doped regions 106 on opposite sides of the word line 110. Here, the word line 110, the dielectric layer 108, the pair of doped regions 106 on opposite sides of the word line 110, and the substrate 100 may collectively serve as the transistor TR of the memory cell MC as discussed in FIG. 1. In greater detail, the word line 110 may serve as the gate electrode of the transistor TR, the dielectric layer 108 may serve as the gate dielectric of the transistor TR, the substrate 100 may serve as the channel region of the transistor TR, and the doped regions 106 may serve as source/drain regions of the transistor TR. The doped regions 106 and the substrate 100 have opposite conductivity types. For example, if the substrate 100 is a p-type substrate, the doped regions 106 are n-type doped regions. If the substrate 100 is an n-type substrate, the doped regions 106 are p-type doped regions.

Referring to FIGS. 4A and 4B, a dielectric layer 122 and a dielectric layer 124 are formed over the substrate 100. The dielectric layer 124 is over the dielectric layer 122, and the dielectric layer 122 is in contact with the substrate 100, the isolation structures 105 and the word line cap layers 112. The dielectric layer 122 and the dielectric layer 124 are made of different material. In some embodiments, the dielectric layer 122 is made of silicon oxide, and the dielectric layer 124 is made of silicon nitride.

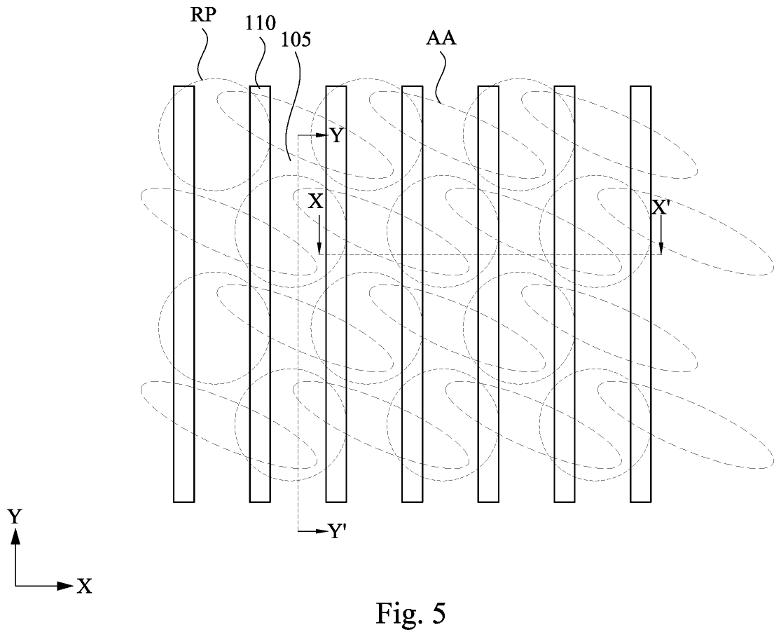

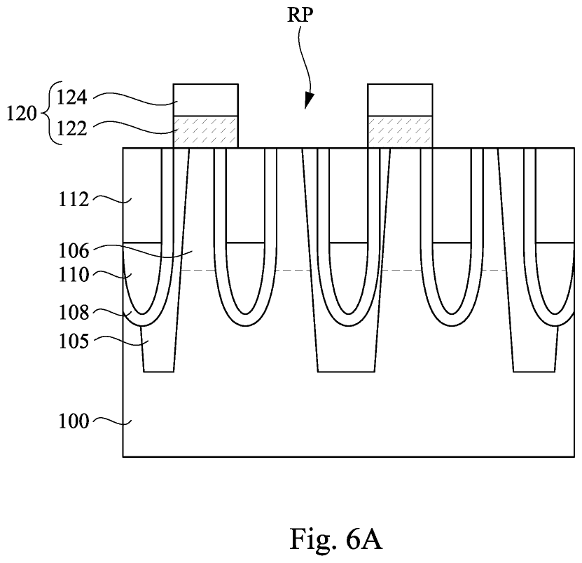

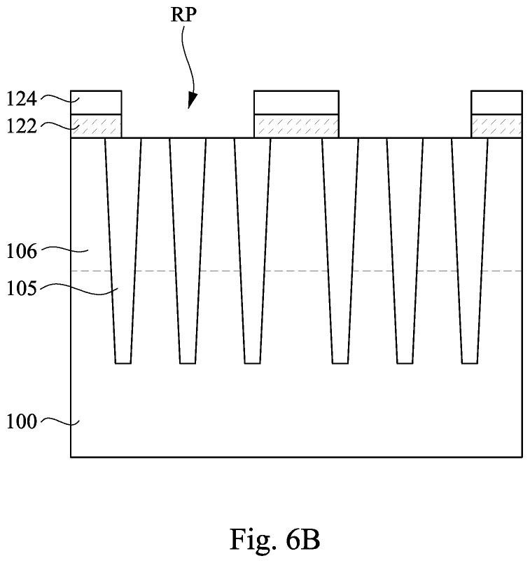

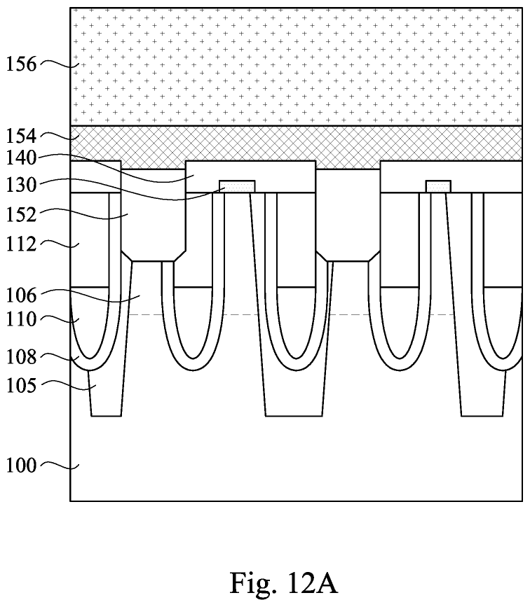

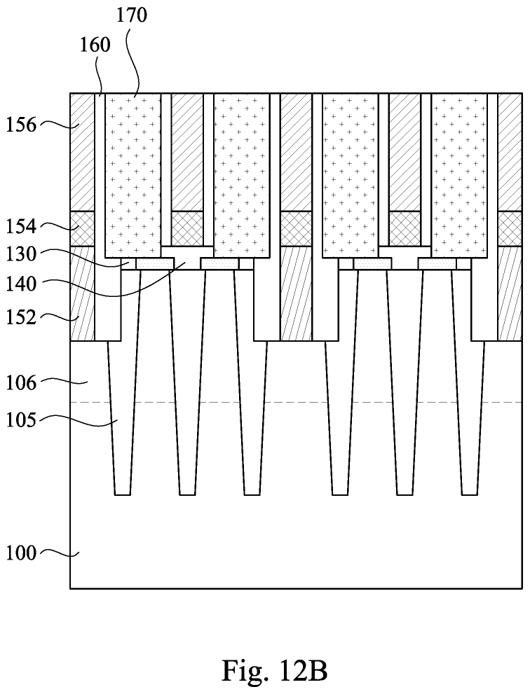

FIG. 5 illustrates a top view of an intermediate stage of forming the memory device in some embodiments of the present disclosure. FIGS. 6A, 7A, 8A, 9A and 10A illustrate cross-section views of forming the memory device taken along line X-X′ in FIG. 5, and FIGS. 6B, 7B, 8B, 9B and 10B illustrate cross-section views of forming the memory device taken along line Y-Y′ in FIG. 5. It is noted that FIG. 5 only illustrates a part of the components, and other components are omitted for simplicity. Referring to FIGS. 5, 6A and 6B, the mask layer 120 is formed over the substrate 100, and the mask layer 120 exposes a first portion of the substrate 100. Specifically, the mask layer 120 is formed by patterning the dielectric layer 122 and the dielectric layer 124. Bit line contact reverse patterns RP are formed in the mask layer 120 after forming the mask layer 120. The bit line contact reverse patterns RP expose the first portion of the substrate 100, a first portion of the word line cap layers 112 and a first portion of the isolation structures 105. The mask layer 120 covers a second portion of the substrate 100, a second portion of the word line cap layers 112 and a second portion of the isolation structures 105. In the process discussed later, the first portion of the substrate 100 will be electrically connected to a cell contact (see FIG. 12B), and the second portion of the substrate 100 will be electrically connected to a bit line contact (see FIG. 12B).

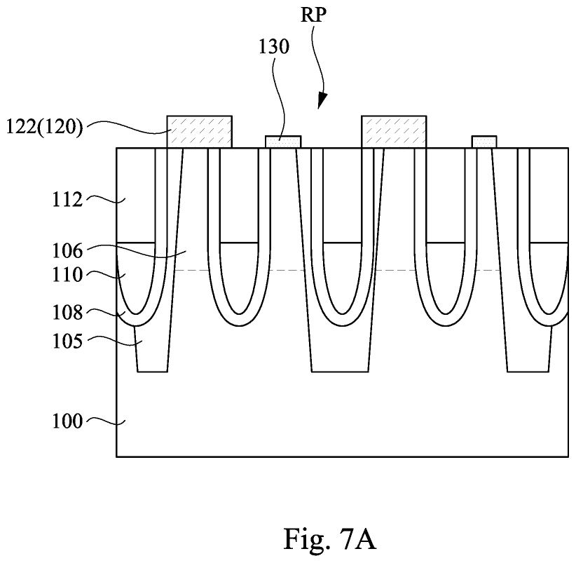

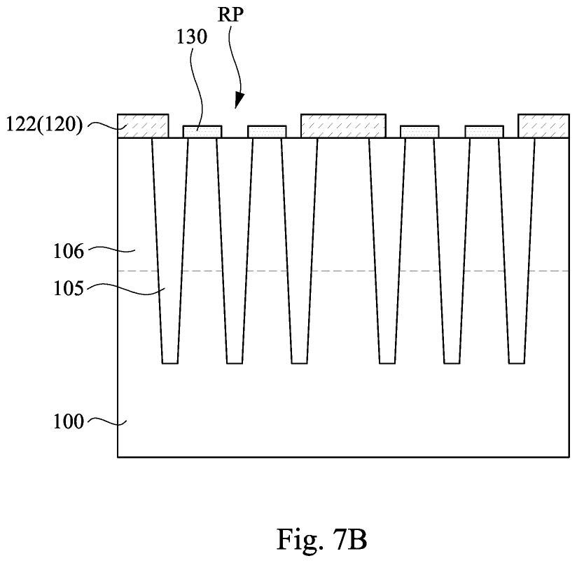

Referring to FIGS. 7A and 7B, the dielectric layer 124 is removed, and then a selective epitaxial growth process is performed to form landing pads 130 over the first portion of the substrate 100. Specifically, the dielectric layer 124 may be removed by an etching process selective to the material of the dielectric layer 124, such that the etching process etches the material of the dielectric layer 124 at a faster rate than etching the material of the dielectric layer 122. After removing the dielectric layer 124, the top surface of the dielectric layer 122 is exposed and the dielectric layer 122 substantially remains intact.

Subsequently, the landing pads 130 are selectively grown over and in contact with the first portion of the substrate 100. During the selective epitaxial growth process, the landing pads 130 completely cover the first portion of the substrate 100, and material of the landing pads 130 may extend to a top surface of the word line cap layers 112 and the isolation structures 105. The bottoms of the landing pads 130 are in contact with the top surface of the dielectric layers 108, the word line cap layers 112 and the isolation structures 105, and are substantially level with the top surface of the word line cap layers 112 and the isolation structures 105. The selective epitaxial layer of the landing pads 130 is controlled, such that the size of the landing pads 130 is in a suitable range. For example, the top surface of the landing pads 130 is lower than the dielectric layer 122. In some embodiments, the landing pads 130 still expose most portions of the word line cap layers 112 and the isolation structures 105. In some embodiments where the substrate 100 is made of silicon, the landing pads 130 grown over the substrate 100 are also made of silicon. After the selective epitaxial growth of the landing pads 130, the contact areas between the active areas AA and subsequent formed cell contacts (will be discussed later in FIG. 12B) are enlarged, and thus the better electrical connection between the active areas AA and subsequent formed cell contacts is provided. In some embodiments, the landing pads 130 may be made of single crystalline silicon. In some embodiments, the landing pads 130 are undoped silicon epitaxial layers. In some other embodiments, the landing pads 130 are doped silicon epitaxial layers, and are formed by an in-situ doping during the selective epitaxial growth process. In some embodiments, if the landing pads 130 are doped, the semiconductor type of the landing pads 130 may be the same as the semiconductor type of the doped regions 106.

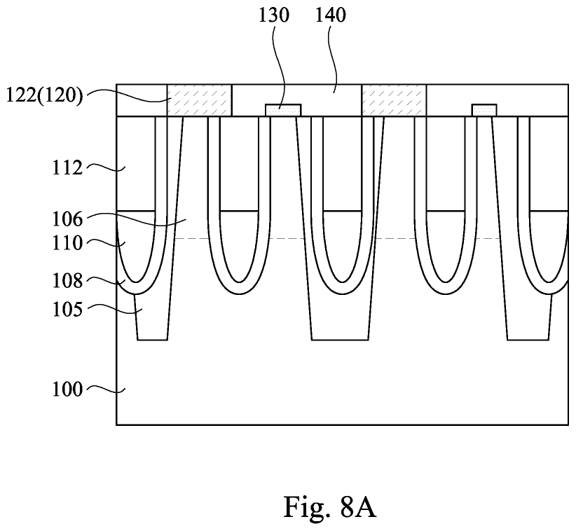

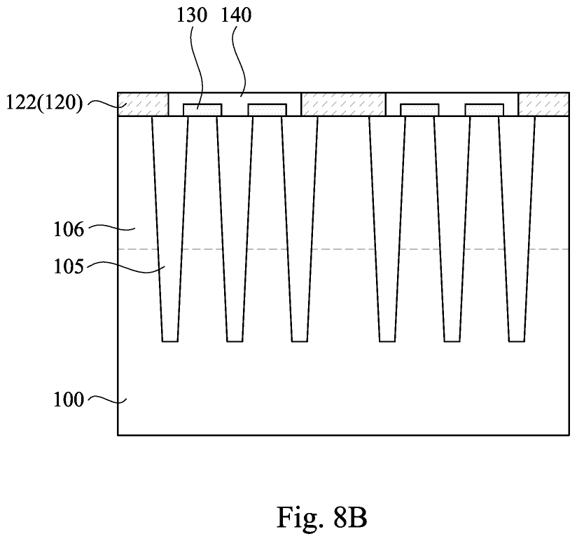

Referring to FIGS. 8A and 8B, a dielectric layer 140 is formed over the landing pads 130, the substrate 100 and the word line cap layers 112. In some embodiments, the dielectric layer 140 is formed by firstly forming a dielectric material layer overfilling the bit line contact reverse patterns RP, and then performing a planarization process to remove the excess portion of the dielectric material layer until the top surface of the dielectric layer 122 is exposed. Therefore, the dielectric layer 140 is formed over the landing pads 130, the substrate 100 and the word line cap layers 112. The top surface of the dielectric layer 140 is substantially level with the top surface of the dielectric layer 122, and the dielectric layer 140 is thicker than the landing pads 130 to completely cover the landing pads 130. The dielectric layer 140 and the dielectric layer 122 are made of different material. In some embodiments, the dielectric layer 140 is made of silicon nitride.

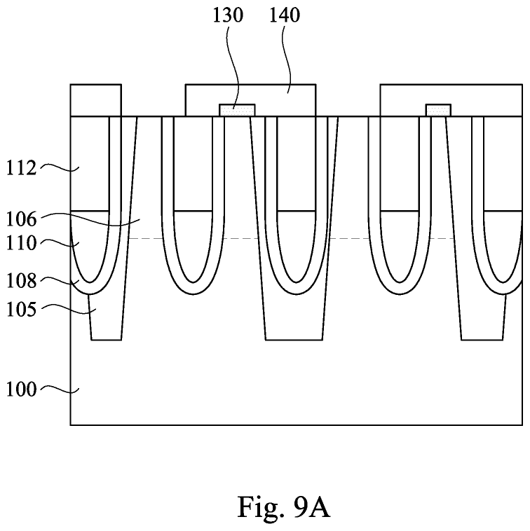

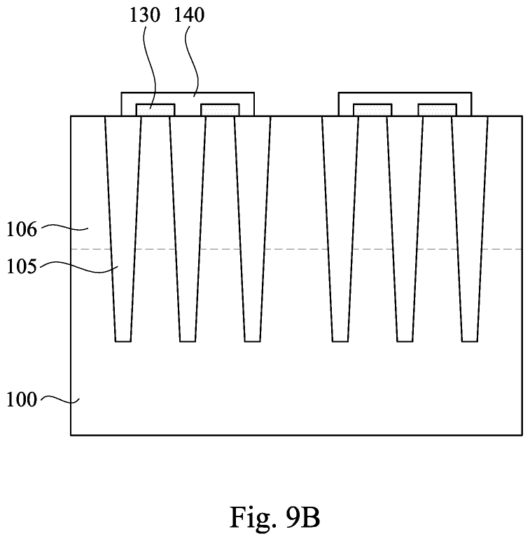

Referring to FIGS. 9A and 9B, the mask layer 120 is removed to expose the second portion of the substrate 100 after forming the dielectric layer 140. Specifically, the mask layer 120 (i.e. dielectric layer 122) may be removed by an etching process selective to the material of the mask layer 120 (i.e. dielectric layer 122), such as the etching process etching the material of the mask layer 120 (i.e. dielectric layer 122) at a faster rate than etching the material of the dielectric layer 140. After removing the mask layer 120 (i.e. dielectric layer 122), the dielectric layer 140 substantially remains intact, and the second portion of the substrate 100, the second portion of the word line cap layers 112 and the second portion of the isolation structures 105 are exposed.

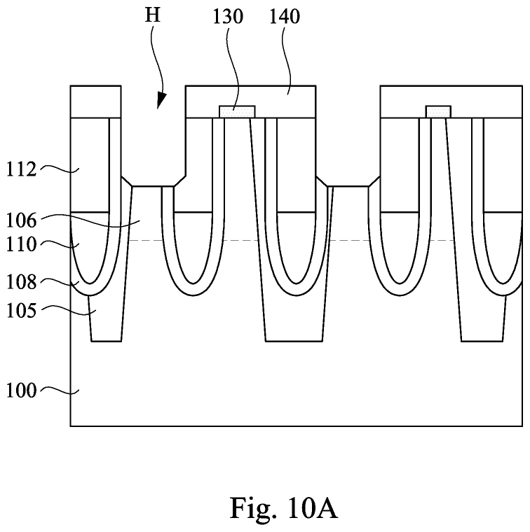

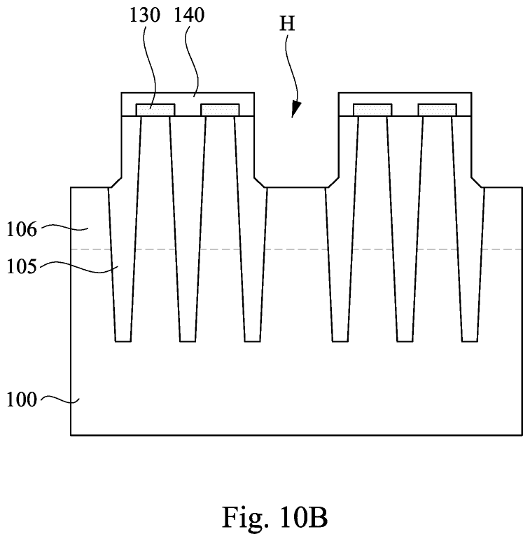

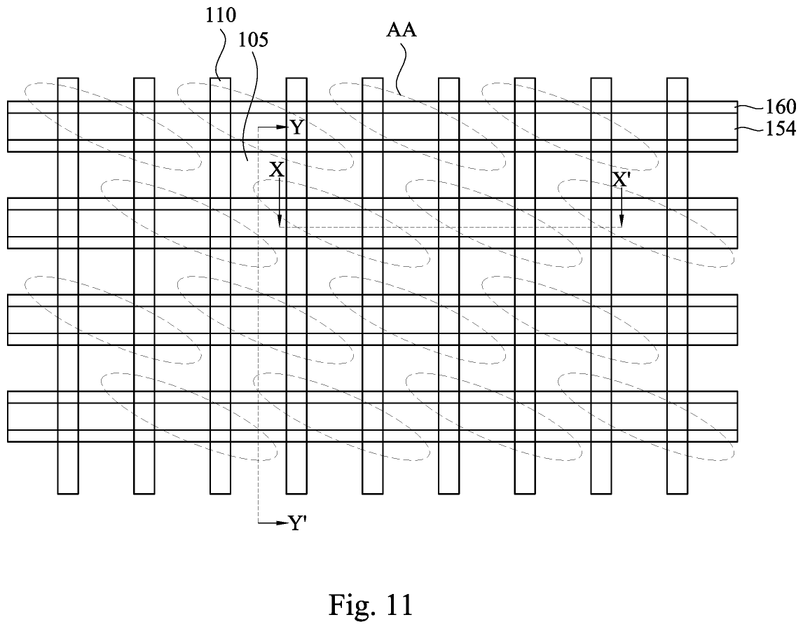

Referring to FIGS. 10A and 10B, bit line contact holes H are formed in the substrate 100 by using the dielectric layer 140 as mask. Specifically, the bit line contact holes H are formed by an anisotropic etching process. The etching process of the bit line contact holes H is controlled, such that the bottom of the bit line contact holes H is at a suitable level. For example, the bottom of the bit line contact holes H is lower than the landing pads 130 and higher than the word lines 110. Therefore, it is ensured that the subsequently formed bit line contacts (see FIG. 12B) are in contact with the active areas AA of the substrate 100 (see FIG. 11) but not in contact with the word lines 110.

FIG. 11 illustrates a top view of an intermediate stage of forming the memory device in some embodiments of the present disclosure. FIG. 12A illustrate a cross-section view of forming the memory device taken along line X-X′ in FIG. 11, and FIG. 12B illustrate a cross-section view of forming the memory device taken along line Y-Y′ in FIG. 11. It is noted that FIG. 11 only illustrates a part of the components, and other components are omitted for simplicity. Referring to FIGS. 11, 12A and 12B, bit line contacts 152, bit lines 154, bit line cap layers 156, spacers 160 and cell contacts 170 are formed. Discussed in greater details, the bit line contacts 152, the bit lines 154 and the bit line cap layers 156 may be formed by sequentially forming a bit line contact layer, a bit line layer and a dielectric layer over the substrate 100 and the dielectric layer 140. The bit line contact layer, the bit line layer and the dielectric layer are then patterned to form the bit line contacts 152 in the bit line contact holes H, the bit lines 154 over the bit line contacts 152 and the dielectric layer 140, and the bit line cap layers 156 over the bit lines 154 respectively. The bit line contacts 152, the bit lines 154 and the bit line cap layers 156 extend along a second direction (such as X-direction) perpendicular to the first direction. After forming the bit lines 154, the top surface of the landing pads 130 is lower than a bottom of the bit line 154, and the bit lines 154 and the landing pads 130 are separated by the dielectric layer 140. Subsequently, the spacers 160 are formed along the sidewalls of the bit line contacts 152, the bit lines 154 and the bit line cap layers 156. After forming the spacers 160, the bottom of the spacers 160 is over the dielectric layer 140, and the spacers 160 and the landing pads 130 are separated by the dielectric layer 140. Subsequently, the cell contacts 170 are formed penetrating the dielectric layer 140 and in contact with the landing pads 130. The landing pads 130 provide larger contact area between the cell contacts 170 and the active areas AA of the substrate 100. Therefore, the cell contacts 170 have a better electrical connection with the active areas AA of the substrate 100. In some embodiments, the bit line contacts 152 are made of conductive material, such as polysilicon, the bit lines 154 are made of conductive material, such as metal, such as tungsten, the bit line cap layers 156 are made of dielectric material, such as silicon nitride, the spacers 160 are made of dielectric material, such as silicon nitride, silicon oxide or combinations thereof, the and the cell contacts 170 are made of conductive material, such as poly-crystalline silicon (polysilicon), metal (such as tungsten), or combinations thereof. In some embodiments, the cell contact 170 may be electrically connected to a capacitor, such as the capacitor CA as discussed in FIG. 1. In some embodiments, a capacitor is in contact with a top surface of the cell contact 170.

The resulting memory device is shown in FIGS. 12A and 12B, the memory device includes the substrate 100, isolation structures 105, the word lines 110, the word line cap layers 112, the landing pads 130, the dielectric layer 140, the cell contacts 170, the bit lines 154 and the bit line contacts 152. The isolation structures are buried in the substrate 100. The word lines are 110 buried in the substrate 100 and extend in a first direction. The word line cap layer 112 are over the word lines 110, in which a top surface of the word line cap layer is substantially level with a top surface of the substrate 100. The landing pads 130 are over and in contact with the substrate 100, the word line cap layer 112 and the isolation structures 105. The cell contacts 170 are over and in contact with the landing pads 130. The dielectric layer 140 covers the landing pads 130, the word line cap layers 112 and the isolation structures 105, and the dielectric layer 140 is in contact with the cell contacts 170 and the landing pads 130. The bit lines 154 are over the word lines 110 and extends in a second direction perpendicular to the first direction. The bit line contacts 152 are below the bit lines 154, and a bottom of the bit line contacts 152 is lower than a bottom of the landing pads 130.

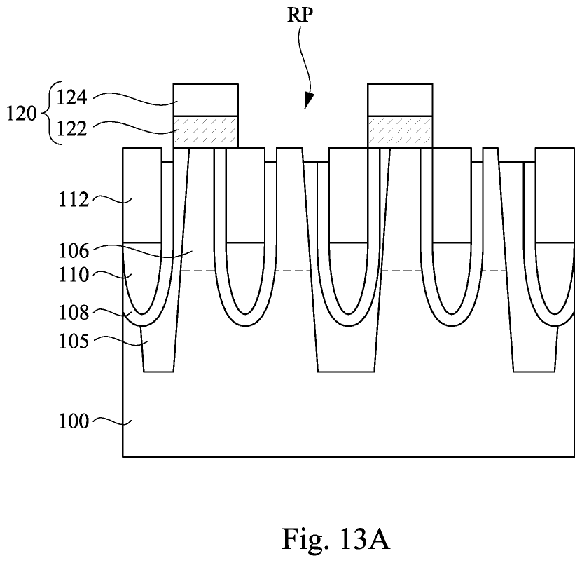

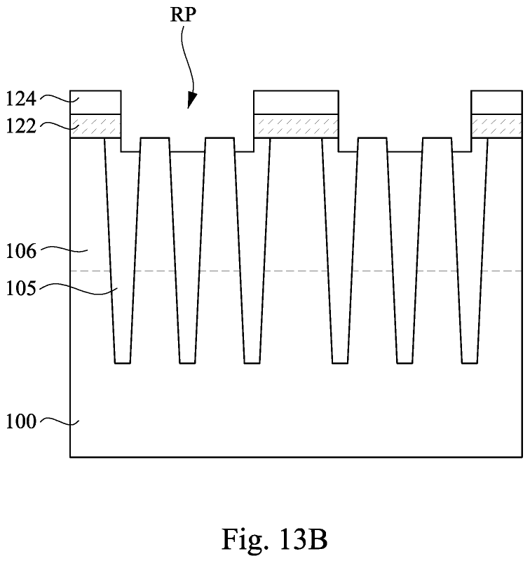

FIGS. 13A, 14A and 15A illustrate cross-section views of forming the memory device taken along line X-X′ in FIG. 5 in some other embodiments, and FIGS. 13B, 14B and 15B illustrate cross-section views of forming the memory device taken along line Y-Y′ in FIG. 5 in some other embodiments. Referring to FIGS. 13A and 13B, after the process in FIGS. 6A and 6B, a cleaning process may be performed prior to the selective epitaxial growth to remove surface oxide of the substrate 100. That is, the cleaning process may be performed prior to the process in FIGS. 7A and 7B. During the cleaning process, the isolation structures 105 and the dielectric layers 108 may be partially etched and recessed, the substrate 100 has a portion protruding over a top surface of the isolation structures 105 and the dielectric layers 108, and the landing pads 130 are in contact with sidewalls of the portion of the substrate 100. Sidewalls of the first portion of the substrate 100 are also exposed. In some embodiments, the cleaning process may be performed by dry etching.

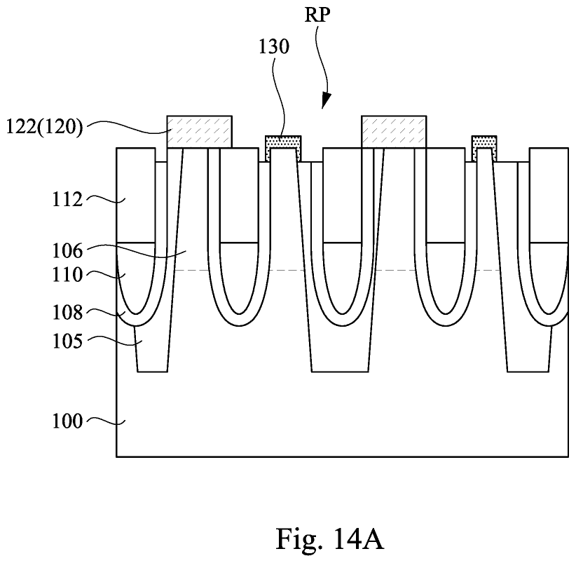

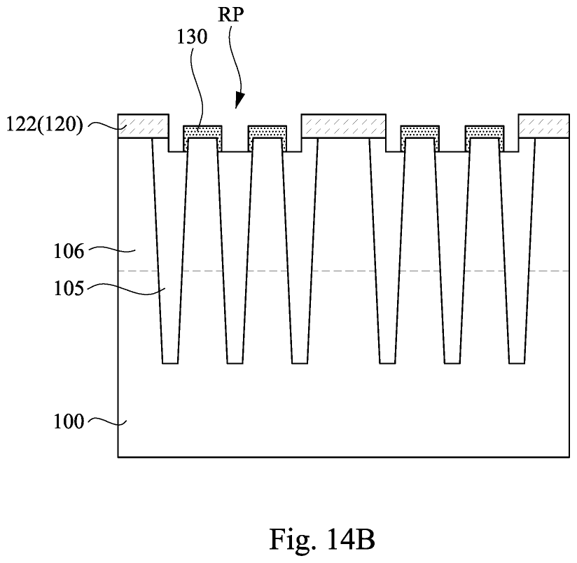

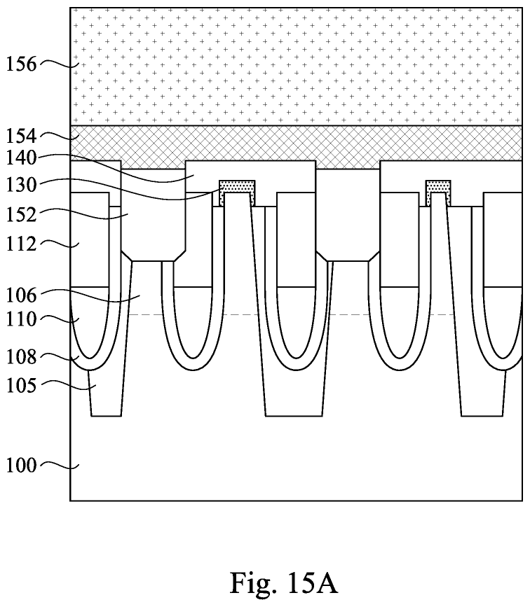

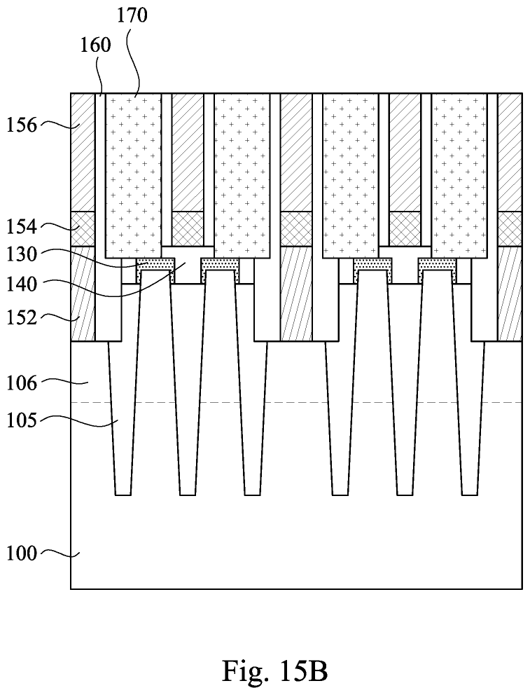

Referring to FIGS. 14A and 14B, a selective epitaxial growth process is performed to form the landing pads 130 over the first portion of the substrate 100 (i.e. the portion of the substrate 100 that is not covered by the mask layer 120). The difference between FIGS. 7A and 7B, and FIGS. 14A and 14B is that the landing pads 130 is formed in contact with the sidewalls of the first portion of the substrate 100, and the landing pads 130 formed in FIGS. 14A and 14B have larger contact area with the substrate 100. Other related details are described in FIGS. 7A and 7B, and are not repeatedly described herein. The resulting memory device is shown in FIGS. 15A and 15B. In the present disclosure, the landing pads 130 provide larger contact area between the cell contacts 170 and the active areas AA of the substrate 100. Therefore, the cell contacts 170 have a better electrical connection with the active areas AA of the substrate 100. Specifically, the landing pads 130 are selectively epitaxial grown region over the substrate 100. In some embodiments, the substrate 100 and the landing pads 130 are made of silicon. During the selective epitaxial growth, the landing pads 130 are grown laterally and vertically from the substrate 100. Therefore, the landing pads 130 provide larger contact area between the cell contacts 170 and the active areas AA of the substrate 100. For example, a portion of the landing pads 130 is between the cell contacts 170 and the word line cap layers 112. Accordingly, the cell contacts 170 may be well connected to the landing pads 130, even if the cell contacts 170 do not perfectly overlap the active areas AA of the substrate 100.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising:
a substrate;
a word line buried in the substrate and extending in a first direction;
a word line cap layer over the word line;
a landing pad over and in contact with the substrate and the word line cap layer;
a cell contact over and in contact with the landing pad; and
a bit line over the word line and extending in a second direction perpendicular to the first direction.

2. The memory device of claim 1, wherein the substrate and the landing pad are made of silicon.

3. The memory device of claim 1, further comprising:
an isolation structure buried in the substrate and in contact with the landing pad.

4. The memory device of claim 3, further comprising:
a dielectric layer covering the landing pad, the word line cap layer and the isolation structure.

5. The memory device of claim 4, wherein the dielectric layer is in contact with the cell contact and the landing pad.

6. The memory device of claim 3, wherein a bottom of the landing pad is substantially level with a top surface of the isolation structure.

7. The memory device of claim 3, wherein the substrate has a portion protruding over a top surface of the isolation structure, and the landing pad is in contact with sidewalls of the portion of the substrate.

8. The memory device of claim 1, further comprising:
a bit line contact below the bit line, wherein a bottom of the bit line contact is lower than a bottom of the landing pad.

9. The memory device of claim 1, wherein a bottom of the landing pad is substantially level with a top surface of the word line cap layer.

10. The memory device of claim 1, wherein a portion of the landing pad is between the cell contact and the word line cap layer.

11. A manufacturing method of a memory device, comprising:
forming a word line and a word line cap layer buried in a substrate, wherein the word line extends in a first direction, and the word line cap layer is over the word line;
forming a mask layer over the substrate, wherein the mask layer exposes a first portion of the substrate;
performing a selective epitaxial growth process to form a landing pad over the first portion of the substrate;
forming a dielectric layer over the landing pad, the substrate and the word line cap layer; and
forming a cell contact penetrating the dielectric layer and in contact with the landing pad.

12. The manufacturing method of claim 11, wherein during the selective epitaxial growth process, the landing pad extends to a top surface of the word line cap layer.

13. The manufacturing method of claim 11, further comprising:
removing the mask layer to exposing a second portion of the substrate after forming the dielectric layer;
forming a bit line contact hole in the substrate by using the dielectric layer as mask; and
forming a bit line contact in the bit line contact hole.

14. The manufacturing method of claim 13, further comprising:
forming a bit line over the bit line contact and the dielectric layer;
forming a bit line cap layer over the bit line; and
forming a spacer lining sidewalls of the bit line contact, the bit line and the bit line cap layer.

15. The manufacturing method of claim 14, wherein the spacer and the landing pad are separated by the dielectric layer.

16. The manufacturing method of claim 14, wherein the bit line and the landing pad are separated by the dielectric layer.

17. The manufacturing method of claim 13, wherein after forming the cell contact, a portion of the landing pad is between the cell contact and the word line cap layer.

18. The manufacturing method of claim 13, wherein a bottom of the bit line contact hole is lower than the landing pad.

19. The manufacturing method of claim 11, further comprising:
performing a cleaning process prior to the selective epitaxial growth process, such that sidewalls of the first portion of the substrate are exposed after the cleaning process.

20. The manufacturing method of claim 19, wherein the landing pad is in contact with the sidewalls of the first portion of the substrate.
